(19) United States
(12) Patent Application Publication
(10) Pub. No.: US 2025/0389052 A1
(43) Pub. Date: Dec. 25, 2025

(54) NOVEL SYNTHESIS OF TWO-DIMENSIONAL INDIUM SELENIDE

(71) Applicant: The Trustees of the University of Pennsylvania, Philadelphia, PA (US)

(72) Inventors: Deep Jariwala, Philadelphia, PA (US); Roy Harold Olsson, III, Phoenixville, PA (US); Seunguk Song, Philadelphia, PA (US)

(21) Appl. No.: 19/066,948

(22) Filed: Feb. 28, 2025

Related U.S. Application Data
(60) Provisional application No. 63/559,239, filed on Feb. 29, 2024.

(51) Int. Cl. C30B 29/46; C30B 25/16; C30B 25/18

(52) U.S. Cl. CPC C30B 29/46; C30B 25/165; C30B 25/18

(57) ABSTRACT

Described herein is two-dimensional (2D) indium selenide (InSe or In₂Se₃) with a combination of favorable attributes. Also described herein are methods of making and using the 2D InSe or In₂Se₃.

### CROSS-REFERENCE TO RELATED APPLICATIONS

This application claims benefit to U.S. Provisional Application No. 63/559,239, filed Feb. 29, 2024, the entirety of which is incorporated by reference herein.

### STATEMENT OF GOVERNMENT SUPPORT

This invention was made with government support under HR0011-21-9-0055 awarded by the Defense Advanced Research Projects Agency. The government has certain rights in the invention.

### TECHNICAL FIELD

The disclosure is directed to two-dimensional indium selenide (InSe or In₂Se₃), and methods of making and using two-dimensional InSe or In₂Se₃.

### BACKGROUND

Two-dimensional (2D) semiconductors, such as indium monoselenide (InSe), have superior electrostatic control and higher mobility than other layered semiconductors, making them ideal for use in next-generation van der Waals (vdW)-integrated electronics. InSe is particularly promising as a channel material for logic devices due to its high Hall mobility (>1,000 cm²V⁻¹s⁻¹ at room temperature), small effective mass for electrons (˜0.14 me), and small asymmetry between the effective masses of electrons and holes (mₕ/mₑ≈2). When combined with highly p-doped Si, InSe can also exhibit a steep subthreshold swing in tunnel field-effect transistors (FETs) with record high on-state current densities (Iₒₙ≈0.3 μA·μm⁻¹) and on-to-off current ratios (Iₒₙ/I_{off}≈10⁶). Additionally, doping or applied strain in InSe layers can lead to both out-of-plane and in-plane ferroelectricity, offering the potential for novel memory devices. Finally, the low melting point of indium is expected to enable low-temperature (<400° C.) growth of high-quality 2D semiconductors, thereby allowing the creation of vertically integrated heterostructure layers on top of silicon logic. However, to date, there have been no demonstrations of large-area growth techniques which lead to the creation of wafer-scale InSe. This has precluded its use as a post-Si channel or Back-End-of-Line (BEOL) compatible channel material.

There is thus a need in the art for growing a polymorph-selective, high-quality, and thickness-controlled 2D InSe or In₂Se₃ thin films through vertical, cold-walled metal-organic vapor deposition (MOCVD).

### SUMMARY OF THE INVENTION

The disclosure is directed to methods of making two-dimension indium selenide (InSe or In₂Se₃). In an aspect, the method comprises depositing on a substrate at least one layer of InSe or In₂Se₃ by MOCVD. In an aspect, the method comprises modulating the flow of In and Se source materials to control the flux ratio of Se/In.

The disclosure is directed to polymorph-selective methods of making epitaxial 2D InSe or In₂Se₃ by MOCVD over 2-inch wafers. In an aspect, the wafer is a c-plane sapphire wafer.

The disclosure is directed to controlling the thickness of the 2D InSe or In₂Se₃ layers using layer-by-layer growth.

The disclosure is directed to using the 2D InSe or In₂Se₃ for gate-tunable electrical transport, with a field-effect mobility comparable to single-crystalline flakes.

The disclosure is directed to 2D InSe or In₂Se₃ layers made by the methods described herein.

### BRIEF DESCRIPTION OF THE DRAWINGS

The present application is further understood when read in conjunction with the appended drawings. For the purpose of illustrating the subject matter, there are shown in the drawings exemplary embodiments of the subject matter; however, while each represents an embodiment of the present disclosure, the presently disclosed subject matter is not limited to the specific methods, devices, and systems disclosed. In addition, the drawings are not necessarily drawn to scale. In the drawings:

FIG. 1a depicts a schematic of the vertical MOCVD system described herein. Dimethyl selenide [DMSe; (CH₃)₂Se] and trimethylindium [TMIn; (CH₃)₃In] are used as the Se and In precursors, respectively, which are delivered by the bubbling system. FIG. 1b depicts a schematic of the crystal structures of indium selenide polymorphs, e.g., β-phase In₂Se₃ (top) and InSe (bottom). FIG. 1c depicts photographs of the monolayer InSe (left) and In₂Se₃ (right) deposited on 2-inch c-plane sapphire, with one half of each wafer displayed for comparison. FIG. 1d depicts molecular flow rate of DMSe (red) and TMIn (blue) precursors as a function of growth time (t) at the growth temperature of 500° C. The delivery and interruption time of DMSe during one pulse period is labeled as td and ti, respectively. FIG. 1e depicts a phase diagram of β-In₂Se₃ and InSe structures as a function of the Se/In ratio and the t_{d}/(tᵢ+t_{d}) ratio during growth 500° C. The t_{d}/(tᵢ+t_{d}) value is 1 when the DMSe flows without interruption (tᵢ=0).

FIG. 2a depicts Raman spectra from InSe (red) and In₂Se₃ (blue) prepared as described herein. FIG. 2b depicts X-ray photoelectron spectroscopy (XPS) analysis of InSe (red) and In₂Se₃ (blue) for In 3d scan. FIG. 2c depicts The X-ray photoelectron spectroscopy (XPS) analysis of InSe (red) and In₂Se₃ (blue) for Se 3d scan. FIG. 2d depicts AFM images of the InSe thin film grown for a growth time of t=0.8t₀. FIG. 2e depicts AFM images of the InSe thin film grown for a growth time of t=1.0 t₀. FIG. 2f depicts AFM images of the InSe thin film grown for a growth time of 1=1.2t₀. FIG. 2g depicts AFM images of the InSe thin film grown for a growth time of t=1.9 t₀. FIG. 2h depicts a summary of the thickness of the InSe as a function of the growth time (t). The error bars stand for their arithmetic average roughness across the area of ˜25 μm². FIG. 2i depicts Raman spectra of the as-grown InSe thin films depending on the growth t; e.g., 1.0 t₀, 1.2 t₀, 1.9 t₀, and 2.7 t₀. The dashed lines indicated the A¹_{1g}, E_{2g}, and A²_{1g} modes of the InSe monolayer grown for 1.0 t₀. FIG. 2j depicts photoluminescence (PL) spectra of the InSe film synthesized via MOCVD as a function of t. The spectra were normalized to their maximum peak after subtracting the background noise from the sapphire substrate.

FIG. 3a depicts cross-sectional scanning transmission electron microscopy (STEM) image of the few-layer InSe. A capping layer of Ir was deposited to minimize damage during the focused ion beam sample preparation. FIG. 3b depicts corresponding selected-area diffraction patterns of the heterointerface in (a), displaying the epitaxial relation between InSe on Al₂O₃ along the [101̅0]Al₂O₃zone axis. FIG. 3c depicts atomic resolution STEM images of InSe along the zone axis of [101̅0]Al₂O₃. FIG. 3d depicts depicts atomic resolution STEM images of InSe along the zone axis of [112̅0]Al₂O₃. FIG. 3e depicts depicts atomic resolution STEM images of InSe along the zone axis of [0001]InSe. FIG. 3f depicts cross-section schematics illustrating the epitaxial relationship between the InSe film and the sapphire (0001) surface. FIG. 3g depicts plan-view schematics illustrating the epitaxial relationship between the InSe film and the sapphire (0001) surface.

FIG. 4a depicts fabricated 2D InSe-based FET with a top-gate geometry. FIG. 4b depicts optical micrograph of top-gated InSe arrays of FETs with a channel length of ˜1 μm and width of ˜20 μm. The right inset shows a FET with top-gate, source, and drain electrodes, with the InSe channel highlighted as a dashed square. FIG. 4c depicts output (I_{ds}-V_{ds}) characteristics for FETs using a few-layer (˜5-6 nm) InSe film at different gate voltages (Vg). FIG. 4d depicts transfer (I_{ds}-V_{g}) characteristics of FETs based on few-layer (red) and monolayer InSe (blue), when a drain-source voltage (V_{ds}) of 1 V was applied. FIG. 4e depicts a boxplot with Gaussian fitting of the field-effect mobility (μ_{FE}). FIG. 4f depicts a boxplot with Gaussian fitting of the on-to-off current (Iₒₙ/I_{off}) ratio of InSe FETs with different thicknesses. The boxplot statistics and Gaussian fitting were performed for the extraction of the mean (square symbols), median (lines in the boxes), standard deviation (error bars), and interquartile range (25-75%; boxes). FIG. 4g depicts Iₒₙ/I_{off} ratio of InSe FET depending on channel thickness with previously reported values of devices prepared by mechanical exfoliation (ME) and direct synthesis (i.e., pulsed-laser deposition followed by annealing (PLD), chemical vapor transport (CVT) and chemical vapor deposition (CVD). FIG. 4h depicts μ_{FE} of InSe FET depending on channel thickness with previously reported values of devices prepared by mechanical exfoliation (ME) and direct synthesis (i.e., pulsed-laser deposition followed by annealing (PLD), chemical vapor transport (CVT) and chemical vapor deposition (CVD).

FIG. 5a depicts an atomic force microscopy (AFM) image of In₂Se₃ film with a thickness of about 5 nm. The dashed line suggests the alignment of the 2D domains grown on the continuous thin film. FIG. 5b depicts Raman mapping image of In₂Se₃. The data was collected for 100 positions with a step size of 1 μm. The inset shows a representative Raman spectrum of the corresponding In₂Se₃ structure. FIG. 5c depicts Raman mapping images of the In₂Se₃ conducted for a A₁(LO+TO) peak. FIG. 5d depicts Raman mapping images of the In₂Se₃ conducted for a A₁(LO) peak. FIG. 5f depicts energy-dispersive X-ray (EDS) spectrum, indicating stoichiometric In₂Se₃ with an estimated Se/In atomic ratio of ˜1.47. FIG. 5g depicts X-ray photoelectron spectroscopy (XPS) analysis of In₂Se₃ In 3d scan. FIG. 5h depicts X-ray photoelectron spectroscopy (XPS) analysis of In₂Se₃ Sc 3d scan.

FIGS. 6a and 6c depict cross-sectional scanning transmission electron microscopy (STEM) image of the few-layer In₂Se₃. The inset of (a) shows the corresponding selected-area electron diffraction (SAED) patterns of the heterointerface in (a), displaying the epitaxial relation between In₂Se₃ on Al₂O₃ [101̅0]_{Al}_{₂}_{O}_{₃}zone axis. FIG. 6b depicts an atomic resolution STEM image of In₂Se₃ along the zone axis of [101̅0]_{Al}_{₂}_{O}_{₃}. FIG. 6d depicts an atomic resolution STEM image of In₂Se₃ along the zone axis of [112̅0]_{Al}_{₂}_{O}_{₃}. Schematics of the crystal structure for In₂Se₃ and Al₂O₃ along the appropriate orientations are included as insets in FIG. 6b and FIG. 6d. FIG. 6e depicts cross-section view schematics illustrating the epitaxial relationship between the InSe film and the sapphire (0001) surface. FIG. 6f depicts plan-view schematics illustrating the epitaxial relationship between the InSe film and the sapphire (0001) surface.

FIG. 7a depicts atomic-resolution cross-sectional STEM image of In₂Se₃ crystal, showing the 3R phase with ABC stacking. FIG. 7b depicts the intensity profile of In layers in In₂Se₃ in a lateral direction. FIG. 7c depicts the intensity profile of Se layers in In₂Se₃ in a lateral direction. FIG. 7d depicts the intensity profile of those captured along a vertical direction. FIG. 7e depicts optical second harmonic generation polar plots of In₂Se₃ for I₁^{2ω}(θ). FIG. 7f depicts optical second harmonic generation polar plots of In₂Se₃ for I₂^{2ω}(θ). The 3m point group symmetry is seen from the following expressions: I₁^{2ω}(θ) ∝d₂₂² (sin 2θ)², and I₂^{2ω}(θ) ∝d₂₂² (cos 2θ)².

FIGS. 8a-d depict piezoelectric force microscopy (PFM) characterizations of an In₂Se₃ thin film when an electric field (E) is applied along in-plane directions. FIGS. 8e-h depict piezoelectric force microscopy (PFM) characterizations of an In₂Se₃ thin film when an electric field (E) is applied along out-of-plane directions. FIG. 8b and FIG. 8f depict AFM images of In₂Se₃ showing their topography. FIG. 8c depicts in-plane PFM phases at the applied voltage of 0 V. FIG. 8d depicts in-plane PFM phases at the applied voltage of 10 V. FIG. 8g depicts the out-of-plane PFM phases at the applied voltage of 0 V. FIG. 8h depicts the out-of-plane PFM phases at the applied voltage of 10 V.

FIG. 9a depicts cross-sectional schematics of a two-terminal In₂Se₃ device. FIG. 9d depicts a ferroelectric semiconductor field-effect transistor (FeSFET) In₂Se₃ device with top gate of 10 nm AlOₓ. FIG. 9b depicts positive-up-negative-down (PUND) measurement of the two-terminal In₂Se₃ device. The pure ferroelectric (FE) switching peaks are observed. FIG. 9c depicts ferroelectric resistive switching of the corresponding device, showing the FE current (inset). FIG. 9e depicts transfer characteristics (I_{ds}-V_{gs}; red) at room temperature of a representative In₂Se₃ FeSFET with 10 nm AlO_{λ} as gate insulator and ALD passivation (V_{ds}=1 V). The gate current (I_{gs}-V_{gs}; gray) is also displayed for the comparison. The device has a channel length of 500 nm and channel thickness of ˜5 nm. FIG. 9f depicts on-state current density values corresponding to the high-resistance state (HRS, gray) and the low-resistance state (LRS, red) at gate voltage (V_{gs}) of 0 V, recorded for 1000 s, showing the retention of the conductance (V_{ds}=1 V).

FIG. 10a depicts piezoelectric force microscopy (PFM) characterizations of an In₂Se₃ thin film schematic showing the electrical field is applied along out-of-plane directions. FIG. 10b depicts AFM images of In₂Se₃ showing their topography. FIG. 10c and FIG. 10d depict the PFM amplitude and phase mapping of In₂Se₃ after the voltage applying of +/−10 V, showing spatial different depending on the voltage due to the polarization up/down (Pᵤₚ and P_{down}). FIG. 10e, FIG. 10f and FIG. 10g depict PFM hysteresis loop measurements at room temperature. FIG. 10e depicts Amplitude raw data of dual a.c. resonance tracking PFM measurements, showing the off-field response. FIG. 10f depicts Off-field PFM amplitude and FIG. 10g depicts phase versus voltage hysteresis loop, showing clear ferroelectric polarization switching under an external electrical field.

FIG. 11a depicts ferroelectric switching behaviors of In₂Se₃ in a cross-sectional schematic of a ferroelectric semiconductor field-effect transistor (FeSFET) In₂Se₃ device with top gate of 10 nm AlOₓ. FIG. 11b depicts output (I_{ds}-V_{ds}) and FIG. 11c depicts transfer characteristics (I_{ds}-V_{gs}; red) at room temperature of a representative In₂Se₃ FeSFET with 10 nm AlOₓ as gate insulator and ALD passivation (V_{ds}=1 V). The gate current (I_{gs}-V_{gs}; gray) is also displayed for the comparison in (c). The device has a channel length of 500 nm and channel thickness of ˜5 nm. FIG. 11d depicts on-state current density values corresponding to the high-resistance state (HRS, gray) and the low-resistance state (LRS, red) at gate voltage (V_{gs}) of 0 V, recorded for 1000 s, showing the retention of the conductance (V_{ds}=1 V). FIG. 11e and FIG. 11f depict device performance benchmark plots with respect to on-off ration, thickness, and retention properties.

### DETAILED DESCRIPTION OF ILLUSTRATIVE EMBODIMENTS

The disclosure may be more fully appreciated by reference to the following description, including the following definitions and examples. Certain features of the disclosed compositions and methods which are described herein in the context of separate aspects, may also be provided in combination in a single aspect. Alternatively, various features of the disclosed compositions and methods that are, for brevity, described in the context of a single aspect, may also be provided separately or in any sub-combination.

Growing high-quality 2D InSe layers has proven difficult due to the complexity of the In—Se phase diagram. Unlike 2D group-VI transition-metal dichalcogenides (TMDs) or 3D III-V compound semiconductors (e.g., GaN, GaAs, InP etc.) which only have one stable polymorph, the binary In—Se system has at least four different stable structures (i.e., InSe, In₂Se₃, In₆Se₇, and In₄Se₃) at room temperature. To achieve phase pure and stoichiometric InSe, a delicate balance of vapor flux between In and Se is necessary. For instance, a Se-rich environment promotes the formation of In₂Se₃ rather than InSe, whereas an In-rich atmosphere leads to a higher possibility of creating the InSe phase. However, the low chalcogen-to-metal ratio, which is necessary for InSe nucleation, is more likely to lead to a 3D island growth as opposed to the desired 2D layer-by-layer growth mode. Excessive In flux during synthesis also poses a problem since it creates 3D In droplets, as has often been observed during the growth of In-based nitrides and chalcogenides. In conventional chemical vapor deposition (CVD), it has been difficult to balance the flux ratio between In and Se needed to achieve layer-by-layer growth. Additionally, using a powder-based precursor in conventional CVD decreases the source flux as a function of growth time, which results in continuous variations in the flux ration with time. Vertical MOCVD is a potential solution as it allows better precursor control and mass production for large-area applications. However, epitaxy of InSe on an insulating substrate has not been demonstrated to date despite its potential to create well-oriented polycrystalline domains.

Described herein is an approach for growing a polymorph-selective, high-quality, and thickness-controlled 2D InSe thin film through vertical, cold-walled MOCVD. By periodically interrupting the Se source during flow-modulated MOCVD, a Se-deficient environment that favors the nucleation of InSe over In₂Se₃ is created. Pulsed flow of the Se precursor also suppresses In-rich droplet formation and facilitates lateral growth of InSe at low growth temperatures (360-500° C.), allowing growth of highly stoichiometric, crystalline thin films on c-plane oriented, 2-inch sapphire (α-Al₂O₃). These growth temperatures are also suitable for BEOL integration in leading edge Si microelectronics, as those temperatures should not exceed ˜550° C. for BEOL process. The resulting crystalline InSe domains are directionally oriented along the crystal structure of the substrate, and the thickness of InSe can be controlled as a function of growth time. Described herein are few-layer InSe transistors with a high on-to-off current ratios (Iₒₙ/I_{off} ratio≈10⁴-10⁵) and two-terminal field effect mobility (μ_{FE}≈2.8 cm²V⁻¹s⁻¹), comparable to those of mechanically exfoliated single crystals of InSe. The results represent a promising step towards creating phase-pure 2D InSe films at wafer scale using methods that can be adapted to other material systems with multiple polymorphs.

In addition, the optical properties of the grown InSe described herein are found to be comparable to CVT-grown bulk crystals. These results demonstrate phase pure epitaxial growth of InSe and offer novel insights into the vapor phase growth of polymorph complex binary 2D chalcogenide systems. This approach to 2D crystal growth can be expected to lead to production of wafer scale electronic-grade 2D III-VI compound semiconductors at low temperatures (360-500° C.) with use in memory, logic and RF amplifier device applications.

Two-dimensional (2D) indium selenide (InSe or In₂Se₃) has attracted significant attention as an ultrathin III-VI semiconductor with a combination of favorable attributes that are comparable to III-V semiconductors and van der Waals 2D transition metal dichalcogenides. Nevertheless, there has been no demonstration of large-area synthesis of 2D InSe or In₂Se₃ due to the complexity of the binary In—Se system and the difficulties in promoting lateral growth.

Described herein is polymorph-selective synthesis of epitaxial 2D InSe or In₂Se₃ by metal-organic chemical vapor deposition (MOCVD) over 2-inch wafers. The polymorph-selective epitaxial growth of InSe or In₂Se₃ on c-plane sapphire was achieved via precursor flow modulation to control the Se/In flux ratio. The layer-by-layer growth allows thickness control over wafer scales with tunable optical properties comparable to those of bulk crystals. Also described herein is gate-tunable electrical transport with a field-effect mobility comparable to single-crystalline flakes. These results indicate that InSe or In₂Se₃ grown by MOCVD could be an effective channel material for back-end-of-line integration in logic transistors.

In some embodiments, the disclosure is directed to a method of making phase-pure InSe or In₂Se₃ comprising depositing on a substrate at least one layer of InSe or In₂Se₃ by MOCVD.

In some embodiments, the at least one layer is epitaxially deposited. In some embodiments, the substrate is a wafer. In some embodiments, the wafer has at least a two inch diameter. In some embodiments, two or more layers are epitaxially deposited. In some embodiments, five or six layers are epitaxially deposited. In some embodiments, the wafer is a wafer selected from a c-plane sapphire wafer, an AlOₓ/Si wafer and an SiO₂/Si wafer. In some embodiments, the wafer is a c-plane sapphire wafer.

In some embodiments, the method further comprises modulating flow of starting material of In and starting material of Se to control a flux ratio of Sc/In. In some embodiments, the flux ratio of Se/In is less than about 2. In some embodiments, the flux ratio of Se/In is from about 0.25 to about 2. In some embodiments, the flux ratio of Se/In is from about 0.5 to about 2. In some embodiments, the flux ratio of Se/In is from about 0.75 to about 2. In some embodiments, the flux ratio of Se/In is from about 1 to about 2. In some embodiments, the flux ratio of Se/In is from about 1.25 to about 2. In some embodiments, the flux ratio of Se/In is from about 1.5 to about 2. In some embodiments, the flux ratio of Se/In to less than about 1.5. In some embodiments, the flux ratio of Se/In is from about 0.25 to about 1.5. In some embodiments, the flux ratio of Se/In is from about 0.5 to about 1.5. In some embodiments, the flux ratio of Se/In is from about 0.75 to about 1.5. In some embodiments, the flux ratio of Se/In is from about 1 to about 1.5. In some embodiments, the flux ratio of Se/In is from about 1.25 to about 1.5. In some embodiments, the flux ratio of Se/In is less than about 1. In some embodiments, the flux ratio of Se/In is from about 0.25 to about 1. In some embodiments, the flux ratio of Se/In is from about 0.5 to about 1. In some embodiments, the flux ratio of Se/In is from about 0.75 to about 1.

In some embodiments, the the flux ratio of Se/In is from about 0.25 to about 0.3; or from about 0.3 to about 0.35; or from about 0.35 to about 0.4; or from about 0.4 to about 0.45; or from about 0.45 to about 0.5; or from about 0.5 to about 0.55; or from about 0.55 to about 0.6; or from about 0.6 to about 0.65; or from about 0.65 to about 0.7; or from about 0.7 to about 0.75; or from about 0.75 to about 0.8; or from about 0.8 to about 0.85; or from about 0.85 to about 0.9; or from about 0.9 to about 0.95; or from about 0.95 to about 1.0; or from about 1.0 to about 1.05; or from about 1.05 to about 1.10; or from about 1.10 to about 1.15; or from about 1.15 to about 1.20; or from about 1.20 to about 1.25; or from about 1.25 to about 1.30; or from about 1.30 to about 1.35; or from about 1.35 to about 1.40; or from about 1.40 to about 1.45; or from about 1.45 to about 1.50; or from about 1.50 to about 1.55; or from about 1.55 to about 1.60; or from about 1.60 to about 1.65; or from about 1.65 to about 1.70; or from about 1.70 to about 1.75; or from about 1.75 to about 1.80; or from about 1.80 to about 1.85; or from about 1.85 to about 1.90; or from about 1.90 to about 1.95; or from about 1.95 to about 2.0.

In some embodiments, the depositing takes place at a temperature of from about 350° C. to about 550° C. In some embodiments, the depositing takes place at a temperature of from about 360° C. to about 500° C. In some embodiments, the depositing takes place at a temperature of from about 400° C. to about 500° C. In some embodiments, the depositing takes place at a temperature of from about 425° C. to about 500° C. In some embodiments, the depositing takes place at a temperature of from about 450° C. to about 500° C. In some embodiments, the depositing takes place at a temperature of from about 475° C. to about 500° C.

In some embodiments, the depositing takes place at a temperature of from about 350° C. to about 360° C.; or from about 360° C. to about 370° C.; or from about 370° C. to about 380° C.; or from about 380° C. to about 390° C.; or from about 390° C. to about 400° C.; or from about 400° C. to about 410° C.; or from about 410° C. to about 420° C.; or from about 420° C. to about 430° C.; or from about 430° C. to about 440° C.; or from about 440° C. to about 450° C.; or from about 450° C. to about 460° C.; or from about 460° C. to about 470° C.; or from about 470° C. to about 480° C.; or from about 480° C. to about 490° C.; or from about 490° C. to about 500° C.; or from about 500° C. to about 510° C.; or from about 510° C. to about 520° C.; or from about 520° C. to about 530° C.; or from about 530° C. to about 540° C.; or from about 540° C. to about 550° C.

In some embodiments, the starting material of In comprises (CH₃)₃ In (TMIn). In some embodiments, the starting material of Se comprises (CH₃)₂Se (DMSe).

In some embodiments, the flow rate of the starting material of Se is pulsed. In some embodiments, the flow rate of the starting material of Se is from about 0.1 mmol/min to about 30 mmol/min. In some embodiments, the flow rate of the starting material of Se is from about 1 mmol/min to about 25 mmol/min. In some embodiments, the flow rate of the starting material of Se is from about 5 mmol/min to about 25 mmol/min. In some embodiments, the flow rate of the starting material of Se is from about 10 mmol/min to about 25 mmol/min. In some embodiments, the flow rate of the starting material of Se is from about 15 mmol/min to about 25 mmol/min. In some embodiments, the flow rate of the starting material of Se is from about 20 mmol/min to about 25 mmol/min. In some embodiments, the flow rate of the starting material of In is from about 0.1 mmol/min to about 30 mmol/min. In some embodiments, the flow rate of the starting material of In is from about 0.5 mmol/min to about 20 mmol/min. In some embodiments, the flow rate of the starting material of In is from about 0.75 mmol/min to about 10 mmol/min. In some embodiments, the flow rate of the starting material of In is from about 1 mmol/min to about 5 mmol/min.

In some embodiments, the at least one layer of InSe or In₂Se₃ is grown for about 30 minutes to about 60 minutes. In some embodiments, the at least one layer of InSe or In₂Se₃ is grown for about 35 minutes to about 55 minutes. In some embodiments, the at least one layer of InSe or In₂Se₃ is grown for about 40 minutes to about 50 minutes. In some embodiments, the at least one layer of InSe or In₂Se₃ is grown for about 45 minutes.

In some embodiments, the disclosure is directed to a layer of phase-pure InSe or In₂Se₃ made by a method described herein.

In some embodiments, the disclosure provides a method of making InSe or In₂Se₃, comprising: depositing on a substrate at least one layer of InSe or In₂Se₃ by metal-organic chemical vapor deposition on a substrate, the substrate optionally comprising sapphire.

In some embodiments, the vapor deposition comprises pulse modulation of precursor gases.

In some embodiments, the at least one layer of InSe or In₂Se₃ is characterized as single-crystalline.

In some embodiments, the at least one layer of InSe or In₂Se₃ is characterized as having a broken symmetry in a 3R structure.

The methods disclosed herein are also applicable to other binary inorganic systems, such as GaSe, GaS, InS, InTe and GaTe.

The following Examples are provided to illustrate some of the concepts described within this disclosure. While the Examples are considered to provide an embodiment, it should not be considered to limit the more general embodiments described herein.

### EXAMPLES

### General Experimental Methods

MOCVD Growth of InSe and In₂Se₃

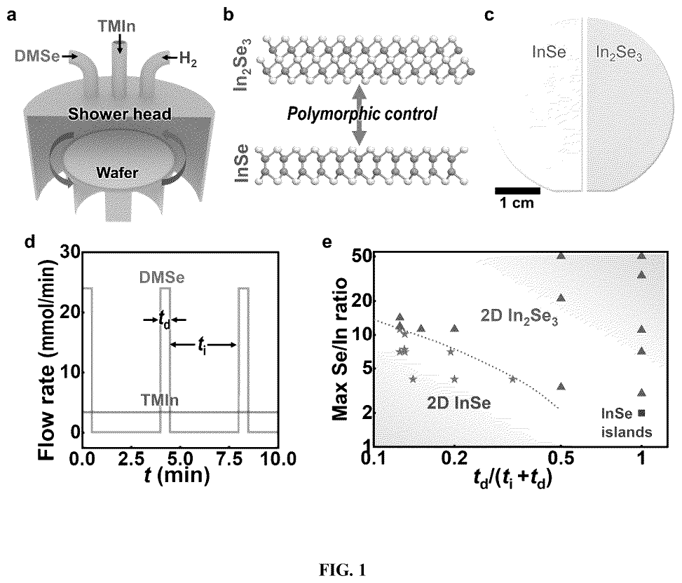

InSe was grown in a showerhead-type vertical MOCVD reactor with an inductively heated TaC-coated graphite susceptor (SMI inc.), depicted in FIG. 1a. TMIn and DMSe were used as In and Se precursors, respectively, and they were delivered into the chamber by using H₂ as a carrier gas. The gas supply system, which includes pneumatic valves, mass flow controllers, pressure controllers, and bubbler temperature controllers, is remotely controlled to modify the molecular mass flow of each precursor. The precursors separates until they enter the chamber to prevent any parasitic reactions in the gas phase. The vapor pressure of TMIn and DMSe was ˜3 and ˜326 Torr, respectively, at the bubbler temperature (32° C.). The growth was mostly conducted at a temperature (T) of ˜500° C. because the pyrolysis of the TMIn and DMSe sources is effective above 480° C.⁴³ and 450-500° C., respectively. Upon reaching the designated T, the substrate was maintained at T for 30 min under a H₂ atmosphere, followed by introduction of precursors at a total pressure of 100 torr for a total growth time, t. The wafer was rotated at ˜50 rpm on the TaC-coated graphite susceptor. For the repeated interruption of the DMSe precursor, the t_{d}/(tᵢ+t_{d}) value of ˜0.14 with a maximum Se/In ratio of ˜10 (depicted in FIG. 1d) was designated. A constant H₂ flow of 10 sccm was maintained during growth. The thickness of InSe was found to be a function of t, with the fully stitched monolayer thin was obtained for a total 1 of ˜45 min (=1.0 t₀). In the case of In₂Se₃ growth, a constant flow of DMSe with the Se/In ratio of 10 was used. The 2-inch Al₂O₃ (0001) (University Wafer) substrate was primarily used as the growth substrate throughout the study due to its surface smoothness and hexagonal crystal structure that matched that of the in-plane InSe structure; nonetheless, the synthesis of 2D InSe on the arbitrary substrate was demonstrated. Before the growth, the target substrates were pre-treated with acetone and isopropanol alcohol (IPA) to remove any organic impurities. The procedure involved immersing the substrates in each solvent mixture more than 10 min.

### Structural Characterizations

Raman spectra, and PL spectra were measured under ambient air using a Horiba LabRam HR Evolution Confocal Microscope with a 100× objective lens (Olympus) and a 633 nm laser with a power of ˜5.5×10⁸ mW·cm⁻² and ˜0.5 μm spot size. The morphology of InSe was characterized by AFM (OmegaScope-R from AIST-NT). STEM images and STEM-EDS spectra were acquired using an aberration (probe)-corrected STEM (JEOL NEOARM). A 4 cm camera length and a 6C probe size with a 40 μm condenser aperture was used, yielding an approximately 62.5 pA probe current and a convergence angle of approximately 27 mrad. TEM images and SAED patterns were acquired using a JEOL JEM-F200 with a One View camera. Both TEM and STEM measurements were operated at 200 kV. The TEM cross-sectional samples were prepared by the Ga⁺ focused-in-beam (FIB) system (FEI Helios G5 DualBeam), utilizing the standard In-situ Lift-out method. This was followed by thinning the sample at progressively lower beam voltages, with 1 keV as the final cleaning step. XPS was characterized using an SSI Spectrometer under a high vacuum (˜10-9 torr) with monochromated Al Kₐ radiation (1486.6 eV), in which the data were corrected using the C signals.

### Electrical Device Fabrications and Measurements

The electrical devices were fabricated using electron-beam lithography (Elionix ELS-7500EX). Polymethyl methacrylate (PMMA) was used as an e-beam resist. The In/Au (10/40 nm) metal contacts were deposited by a thermal evaporator (Kurt J. Lesker Nano-36). The gate dielectric layers of Sb₂O₃ (10 nm) and HfOₓ (10 nm) were deposited by thermal evaporation and atomic-layer deposition, respectively, followed by the deposition of gate electrodes (Ti/Au (10/40 nm)) by e-beam evaporation (Kurt J. Lesker PVD-75). The electrical measurements were conducted at room temperature using a probe station (Lake Shore) combined with a semiconductor analyzer (Keithley 4200). All statistically estimated values in the paper are reported as “average±standard deviation,” unless otherwise specified.

### Example 1-Synthesis and Characterization of 2D InSe

To synthesize 2D InSe layers, MOCVD in a cold-walled, vertical reactor with precursors of trimethylindium [TMIn; (CH₃)₃ In] and dimethyl selenide [DMSe; (CH₃)₂Se] as the In and Se sources, respectively (FIG. 1a), was performed. The individual pressure controllers and mass flow controllers allow subtle control of molecular flow rates of each precursor, which dominantly impacts the resulting polymorphic crystal in the binary In—Se system (FIG. 1b). For example, for a molecular flow rate of Se higher than In (i.e., high Se/In ratio >2), the growth typically results in the formation of In₂Se₃ (FIG. 1b, top). The higher flux of Se is accommodated in the In₂Se₃ crystal structure, as it has an additional Se atomic layer in between two In—Se layers (FIG. 1b, bottom). The vertical delivery of precursors from the showerhead to the rotating substrate in the system (FIG. 1a) results in homogeneous mixing and flow of precursors supporting the homogenous nucleation and growth of the 2D crystals across the 2-inch wafer (FIG. 1c), which is a significant benefit over horizontal CVD (See methods for additional details on precursors, reactor, and growth). The c-plane sapphire serves as a substrate for van der Waals epitaxy because of its matching of both hexagonal lattice symmetry and supercells with InSe, despite its lattice mismatch of ˜ 19% (a_{InSe}=4.01 Å; a_{Al}_{₂}_{O}_{³}; =4.76 Å).

In order to expand the InSe growth window, the flow rate of DMSe was varied as a function of growth time (t), as illustrated in FIG. 1d. A pulsed DMSe flow promoted InSe nucleation rather than In₂Se₃ due to the momentarily induced Se deficiency in the growth environment. FIG. 1e depicts the growth phase diagram, which shows that the formation of InSe and In₂Se₃ depends heavily on the maximum Se/In ratio and the fraction of the unit delivery time of DMSe (t_{d}) in the total pulse time (tᵢ+t_{d}) (i.e., max Se/In ratio vs. the value of t_{d}/(tᵢ+t_{d})). When the DMSe flow rate is held constant (t_{d}/(tᵢ+t_{d})=1, as tᵢ=0), the growth window for InSe is narrow; for instance, materials grown with a Se/In ratio higher than 2 is always In₂Se₃ instead of InSe. A Se/In ratio below ˜2 results in the production of InSe islands resulting from the Se-rich condition. Furthermore, InSe growth under constant DMSe flow and with a small Se/In ratio of ˜2 leads to the formation of a droplet-like (not 2D) morphology due to the excess In flux during the MOCVD. This leads to the formation of metallic In or In-rich InSe islands. On the other hand, pulsed flow of DMSe (i.e., t_{d}/(tᵢ+t_{d})<1) widens the growth window for the formation of InSe. This indicates that providing a periodical In-rich growth environment favors InSe nucleation. Further, even a high Se/In ratio of ˜11 during a pulsed growth (t_{d}/(tᵢ+t_{d})<1) resulted in the synthesis of an atomically thin InSe layer. The robust growth window suggests that this approach can be adapted to different reactors, as well as other binary systems with even more complex phase diagrams. In addition, the modulated flow of precursor promotes the ripening of the nuclei and their lateral growth, leading to coalescence into a continuous high-quality 2D InSe, similar to the previous reports for TMDs. To substantiate this further, the crystalline quality and growth morphology (e.g., 2D or 3D growth modes and formation of In-rich droplets) as a function of t_{d} and tᵢ values was characterized.

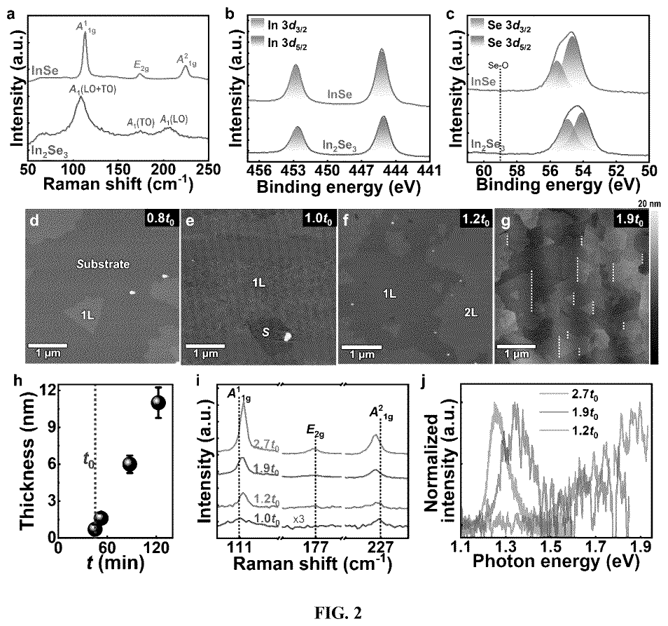

The 2D polymorphs of InSe were identified using Raman spectroscopy, as the representative signals from InSe (red) and In₂Se₃ (blue) (FIG. 2a). Three A₁ vibrational modes for β-phase In₂Se₃ and two A_{1g} and E_{2g} modes for InSe are displayed. The broad full-width at half maximum (FWHM) of ˜11 cm⁻¹ of the first A₁ peak at ˜108.5 cm⁻¹ of β-In₂Se₃ is caused by the existence of two mixed longitudinal (LO) and transverse (TO) components, not poor crystalline quality. Raman mapping of the InSe film grown by pulsed DMSe flow shows uniformity over a large area of the film. The presence of expected characteristic InSe peak positions, uniform intensities, and uniform FWHM across a large area (˜100 μm) without any observable signatures of In₂Se₃ indicates that the monolayer InSe film grown on 2-inch sapphire is homogeneous. The large-scale homogeneity is also indicated by the uniform contrast in both the photograph (FIG. 1c) and the corresponding optical microscopy image.

X-ray photoelectron spectroscopy (XPS) of the In 3d and Se 3d peaks also indicates that pure InSe has been formed, as opposed to In₂Se₃ (FIGS. 2b, c). The In 3d_{3/2} and In 3d_{5/2} core levels of InSe are located at lower binding energies than those of In₂Se₃ due to the higher positive oxidation state of the compounds (FIG. 2b). The Se 3d_{3/2} and 3d_{5/2} of In₂Se₃ are located at lower energy levels than those of InSe because of the loss of valance charge of the Se atom (FIG. 2c). The absence of Se—O bonds at ˜58.6 cV implies that MOCVD produces high-quality InSe or In₂Se₃ without oxide impurities. The atomic ratio between Se and In as determined by XPS (i.e., at. % of Sc/In) of the as-grown film is ˜1.03, very close to the ideal stoichiometry of InSe (i.e., 1.00). In contrast, the at. % of Se/In of as-grown In₂Se₃ thin film is higher (˜1.30).

The growth of phase-pure InSe by the pulsed MOCVD is found to be universal irrespective to target substrates as the selection of InSe and In₂Se₃ nucleation relies strongly on the flow rate control (FIG. 1e). Specifically, InSe is synthesized with the optimized recipe regardless of the target substrates (i.e., amorphous SiO₂/Si, AlOₓ/Si, and sapphire) as suggested by Raman spectra and X-ray diffraction (XRD) patterns (the characterized films are multilayer with a thickness larger than ˜5 nm.). The X-ray diffraction patterns display only (0021) peaks of the crystals, consistent with the formation of InSe (JCPDS database card No.: 34-1431, where a and c are 4.005 Å and 16.640 Å, respectively). The observation of strong (0021) peaks indicates the growth of c-plane oriented InSe on arbitrary substrates. The synthesis of InSe with (0021) texture is also possible at lower temperatures (˜360 or 400° C.). This low growth temperature suggests that it is possible to directly integrate InSe with electronic components at temperatures compatible with complementary metal-oxide semiconductor (CMOS) BEOL processes.

It is possible to control the thickness of 2D InSe thin film by adjusting the growth time, consistent with the observation of a layer-by-layer growth mode (FIGS. 2d-g). In particular, a small total flow (<22 sccm) leads to a low growth rate, with growth rate being a function of growth time (t). For thin films grown with a growth time t of ˜35 min (˜0.8 t₀, and to denotes the time t when a continuous monolayer film formed; FIG. 2e), small domains of monolayer InSe are observed via AFM (FIG. 2d). A monolayer InSe film with a full wafer coverage is observed when the growth time is ˜45 min (=1.0 t₀). Despite some bilayers and tri-layers are also observed at 1.0 t₀, their coverage is negligible (˜4.0±2.8% of the total area). A growth time of 1.210 allows for the further nucleation of InSe domains on the initial monolayer InSe film (FIG. 2f). A much longer growth time of ˜1.9 to results in the synthesis of additional multilayers of InSe, where the edges of the single domains tend to align along one direction (FIG. 2g). This indicates that the newly formed crystalline layers are synthesized coherently, with well-defined orientations with respect to the underlying substrate (i.e., c-plane sapphire). In other words, the subsequent layers grow epitaxially. The thickness of the thin films grown for 1.9 to and 2.7t₀ are estimated to be ˜5.9±0.7 and ˜11.1±1.2 nm (average±roughness) (i.e., ˜7 and ˜14 layers), respectively. The increase in roughness over t suggest that the layer coverage is not strictly uniform, because the faster homoepitaxy of InSe on beneath layer (e.g., lateral growth rate of ˜1.1 mm/min, estimated from the sapphire dimensions and t-dependent thicknesses), compared to the heteroepitaxy of InSe on sapphire (e.g., lateral growth rate of ˜7.5 mm/min), may induce variations on the growth. This is attributed to the higher growth rate of the homoepitaxy to the prevention of lattice mismatching that allows the energetically favorable process. It should be also noted that an estimated vertical growth rate is ˜0.02-0.13 nm/min (˜1-8 nm/h, estimated from the linear slopes in FIG. 2h), faster than the growth rates of other MOCVD of group-VI 2D sulfides or selenides. This faster growth rates may be attributed to the increase in the migration of precursors on the surface by flow modulation.

Raman and photoluminescence (PL) spectra from films of different thickness are shown in FIGS. 2f, g. The Raman spectra of InSe grown for 2.7 to (with a thickness of ˜11 nm) show Raman vibrational modes of A¹_{1g}, E_{2g}, and A²_{1g} at ˜112.9, 176.7, and 224.9 cm⁻¹, respectively. As growth time and corresponding thickness increase, the difference between out-of-plane modes (A¹_{1g} and A²_{1g}) becomes larger (FIG. 2i) due to variations in interlayer coupling, consistent with prior literature reports. Despite the drastic decrease in Raman intensities in the monolayer (grown for 1.0 t₀) compared to those of multilayers (as expected for monolayer), the even distribution of Raman signals in Raman mapping indicates that the monolayer is synthesized in a uniform manner across the microscale region. The PL spectra from InSe film prepared at different growth times, normalized to the maximum peak intensities, also shows a thickness-dependent optical properties (FIG. 2j). Since the InSe films below ˜7 layers have an indirect band gap, the intensity of PL emission from the film grown for 1.0-1.9 to (0.9-5.9 nm) is far smaller than that of 2.7 to (˜11 nm). Furthermore, the excitonic transition energy of the layers is distinct, and depends upon the growth time due to the thickness-dependence of quantum-confinement effects (FIG. 2j). The PL emission of the as-grown InSe film indicates the preparation of crystals without substantial disorder or gap states. In the case of the as-grown InSe monolayer, no distinct PL signal is detected due to either its indirect transition, air-induced oxidation (which is severer than multilayer), or higher bandgap (˜2.0 eV) to be observed using a 633 nm laser. However, band-to-band transitions in the as-grown InSe monolayer are apparent in the reflectance spectra and the ellipsometer measurements of the complex refractive index (η=n+ik). These observations are indicate that the monolayer has a relatively low defect density.

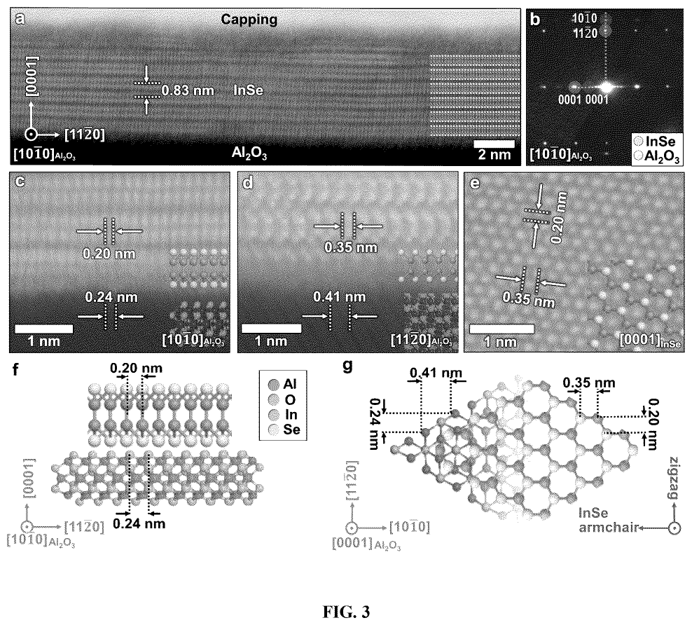

Scanning transmission electron microscopy (STEM) has been used to investigate the atomic scale crystal structure of few-layer InSe synthesized by pulsed DMSe flow (FIG. 3). A cross-sectional STEM image of the InSe layer along the zigzag direction ([112̅0]_{InSe}) is shown in FIGS. 3a-c. The high-angle annular dark field (HAADF) STEM image in FIG. 3a shows the layer-by-layer structure of InSe with clearly visible vdW gaps. The interlayer distance along the [0001] direction is measured as ˜0.83 nm, consistent with AFM measurements from the monolayer (FIGS. 2d-g) and previous reports for InSe₃. The atomic configuration resolved in STEM (FIGS. 3a, c) shows a pattern of Se—In—In—Se, and indicates the formation of ˜5-6 layers of InSe, instead of the formation of In₂Se₃. The corresponding selected-area diffraction pattern (SAED) in FIG. 3b indicates that the InSe grown on sapphire (0001) is single-crystalline, with an epitaxial relation of (0001)_{InSe}//(0001)_{Al}_{₂}_{O}_{₃}; and [101̅0]_{InSe}//[112̅0]_{Al}_{₂}_{O}_{₃}). The measured interplanar spacing of (101̅0)_{InSe} and (112̅0)_{InSe} (FIGS. 3c, d) is ˜0.35 nm and ˜0.20 nm, respectively, which is in good agreement with those previously reported for 2D InSe structures^{31,32}. The plan-view STEM images (FIG. 3e) and the corresponding diffractograms show that this region of the thin film has a three-fold symmetry along the zone axis, consistent with the formation of a 2D InSe crystal structure. The stoichiometry of the film as determined by energy dispersive X-ray spectroscopy (EDS) are consistent with the formation of InSe, without carbon-related impurities.

In conjunction with the SAED (FIG. 3b), the extracted atomic distances of Al₂O₃ planes and the coordinated InSe structures in the atomically resolved STEM images (FIGS. 3c-e) suggest that the InSe zigzag direction is perpendicular to the zone axis of sapphire (FIG. 3c) and the armchair direction is parallel to the <101̅0>_{Al}_{₂}_{O}_{₃}, (FIG. 3d). The orientation-controlled InSe on the c-plane sapphire implies that epitaxy is possible, consistent with the schematics presented in cross-sectional and top-view atomic illustrations of FIGS. 3f, g. Calculations based on the measured lattice spacings of InSe aligned on Al₂O₃ in <101̅0>_{Al}_{₂}_{O}_{₃} and <1120>_{Al}_{₂}_{O}_{₃}. directions suggest that there is nearly a commensurate relationship between the 6 InSe unit cells (6×a_{InSe}=24.1 Å) and the 5 α-Al₂O₃ unit cells (5×a_{Al}_{₂}_{O}=23.8 Å), with a supercell mismatch of only 0.96%. This suggests that individual epitaxially grown InSe grains merge together during MOCVD to form small-angle grain boundaries (GBs) with single orientation, as directionally aligned InSe domains are observed in the AFM images (FIG. 2g). Furthermore, no GBs were observed during cross-sectional STEM analysis of the InSe along the zigzag direction over several μm length of the imaging. The epitaxial growth mode of InSe also suggests that it may be possible to grow unidirectional InSe single crystals using sapphire wafers cut along different crystallographic orientations in the future.

### Example 2-Electrical Transport Properties of 2D InSe

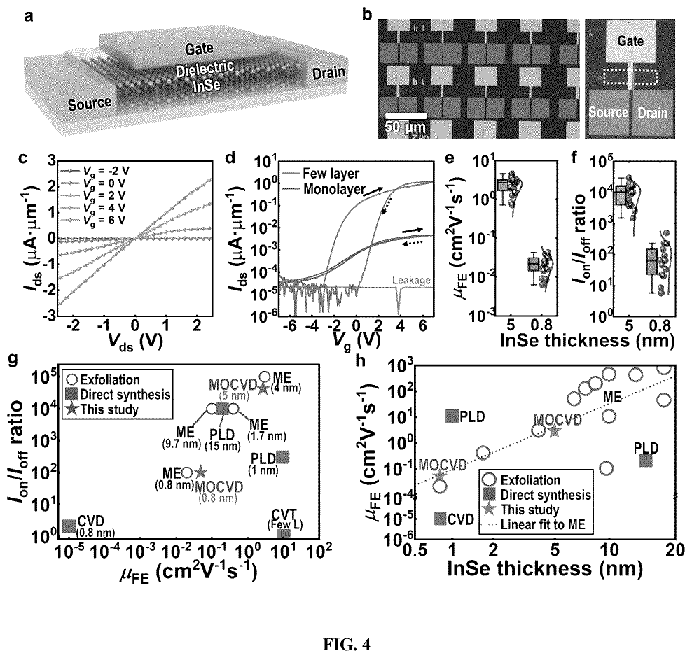

The electrical transport of the InSe films is characterized using two-terminal FET devices at room temperature (FIG. 4).

The electrical transport of the InSe films is characterized using two-terminal FET devices at room temperature (FIG. 4). Device fabrication is conducted using a top-gate geometry with high-k dielectric layers (i.e., Sb₂O₃/HfO₂) to avoid a wet-transfer process that can degrade the channel by severe oxidation³ (FIG. 4a, FIG. 4b). The FETs arrays based on few-layer InSe (grown for 1.9 t₀) demonstrate gate-modulated electrical conductance, as indicated in its representative output curve (FIG. 4c). The corresponding transfer characteristic of few-layer InSe FET also indicates the gate-tunable transport (FIG. 4d, red curve), while demonstrating the higher Iₒₙ (˜1.11 μA/μm) and higher Iₒₙ/I_{off} ratio (>10+) compared to those of monolayer FET (i.e., Iₒₙ of ˜4 nA/μm and Iₒₙ/Loff of ˜ 102; FIG. 4d, blue curve). The significant electrical property degradation in the monolayer (compared to the few-layer InSe) may be attributed to severe carrier scattering at the substrate interface. On the other hand, the hysteresis of the transfer curve is more prominent in the few-layer InSe (e.g., Vin shift of ˜3 V) when compared to the monolayer, probably affected by the enhanced sliding ferroelectricity in the thicker InSe. Charge trapping-induced hysteresis is negligible because the monolayer does not show Vₜₕ shift despite the same oxide dielectric is used as a gate. The emergence of conductance hysteresis indicates that our synthetic few-layer InSe can be used for novel non-volatile electrical device applications.

The successfully fabricated FET arrays enable the statistical analysis of electrical properties of InSe depending on thickness, utilizing a large number of devices (>30 in total). The boxplots effectively illustrate the distribution of data (circle symbols) well-fitted to a Gaussian function (black curves), where the data points fall within the standard deviations (whiskers), particularly for InSe with a 5 nm thickness (FIG. 4e, FIG. 4f). The few-layer InSe FET exhibits an averaged Iₒₙ/I_{off} value (˜2.8 (±1.2)×10⁴), which is two orders of magnitude higher than that of monolayer FET (˜1.2 (±0.4))×10²). Furthermore, the averaged two-terminal μ_{FE} of the few-layer InSe (˜2.46±1.13 cm²V⁻¹s⁻¹) is higher compared to the monolayer InSe (˜0.021±0.012 cm²V⁻¹s⁻¹), and the best μ_{FE} of our few-layer InSe device approaches ˜4.5 cm²V⁻¹s⁻¹ (˜0.04 cm²V⁻¹s⁻¹ for the monolayer). Notably, the Iₒₙ/I_{off} value of ˜ 104-105 achieved in the few-layer InSe FETs is the highest among previously reported synthesized InSe-based FETs, and μ_{FE} value (˜2.46±1.13 cm²V⁻¹s⁻¹) is also the higher compared to FETs exhibiting proper switching behavior (i.e., Iₒₙ/I_{off} ratio >103) (see comparison in FIG. 4g).

To ensure a fair benchmarking of μ_{FE} of our few-layer and monolayer InSe FETs in comparison to other literature values, we further plot the μ_{FE} values based on the InSe thickness in FIG. 4h. The obtained μ_{FE} (˜2.46±1.13 cm²V⁻¹s⁻¹) in our 5-nm-thick InSe is higher than most literature values (˜0.2-3.0 cm²V⁻¹s⁻¹) for mechanically exfoliated or directly grown InSe with thicknesses below 6.5 nm (FIG. 4h). Additionally, the PHE of monolayer InSe (˜0.021±0.012 cm²V⁻¹s⁻¹) also outperforms exfoliated⁵⁰ and CVD-grown monolayers (˜Oct. 5, 2010-2 cm²V⁻¹s⁻¹). The high LIFE of our few-layer and monolayer InSe, relative to previously reported values, implies that scattering of carriers due to in-plane crystallographic tilt or grain-boundaries is negligible, consistent with our observation of well-oriented polycrystalline domains in the epitaxially-grown InSe.

Previous reports have demonstrated high mobility of bulk InSe layers, surpassing ˜ 100 cm²V⁻¹s⁻¹. However, mobilities above ˜ 10 cm²V⁻¹s⁻¹ have only been observed in InSe layers thicker than ˜6.5 nm (FIG. 4h) when combined with specific surface treatments, such as dry oxidation, PMMA/HfOₓ encapsulation, or surface charge doping by deposition In. These surface treatments of the InSe channel in bottom-gate FET are not universally applicable to top-gate, double-gate, or gate-all-around device architectures due to limitations in applying gate bias through the treated surface. Furthermore, these thick InSe layers (>6.5 nm) are not promising for ultrathin body channels, considering that typical Si body widths range from ˜4-10 nm in a 10-nm-node FinFET technology. In contrast to bulk InSe, few-layer 2D InSe exhibits lower mobility due to the larger Schottky barrier height and the stronger charge impurity scattering. The theoretical phonon-limited carrier mobility of few-layer InSe decreases nearly linearly with the number of layers from 10 (˜8 nm) due to the crossover of the electronic density of states from 3D to 2D. Hence, we further emphasize that our few-layer InSe, despite its thinness (˜5 nm), showcases impressive characteristics, including high PFE (˜2.46±1.13 cm²V⁻¹s⁻¹) and high Iₒₙ/off value (˜2.77× 10⁴) (comparable to those of mechanically exfoliated single crystals with similar thickness, as indicated by the linear fit in FIG. 4h).

The MOCVD-grown, atomically-thin InSe is found to substantially suffer from air degradation in comparison to bulk InSe, indicating that further improvement of device performance could be possible through encapsulation using passivation layers. Additionally, optimization of contact electrodes on InSe would be beneficial in realizing even higher AFE, as the operation is significantly affected by Schottky barrier height and contact resistance at the metal-semiconductor junction. For instance, in the experiments, the In/Au contact electrode resulted in better transport behavior than those with Ti/Au and only Au, suggesting that further improvements in the contact interface should allow for efficient carrier injection. The electronic quality of the MOCVD-grown vdW InSe and the demonstrated ability to grow on various substrates, indicates that the synthesis is promising for the fabrication of high-performance electronic devices for future hetero-integration in high-performance microelectronics.

### CONCLUSIONS

The growth of thickness-controlled, phase-pure InSe atomic layers via MOCVD using pulsed injection of the Se precursor DMSe has been demonstrated. The pulsed flow of DMSe is found to create suitable growth conditions for 2D InSe nucleation and subsequent lateral growth. The epitaxial growth of high-quality, highly stoichiometric InSe thin films on c-plane sapphire is confirmed through structural and optical characterization. Furthermore, two-terminal FETs fabricated using few-layer InSe are found to have high Iₒₙ/off ratios of ˜ 104-105 and μ_{FE} of ˜2.8 cm²V⁻¹s⁻¹, which are comparable to those of mechanically exfoliated single-crystalline flakes with a similar thickness. In addition, the optical properties of the grown InSe are found to be comparable to CVT-grown bulk crystals.

### Example 3-Ferro Electrical Properties of Epitaxial 2D β-Phase In₂Se₃

In₂Se₃ thin films with controlled thickness using a vertical, cold-walled metal-organic chemical vapor deposition were successfully grown with high-quality. Through comprehensive structural analysis and characterization, the epitaxial relationship between In₂Se₃ and sapphire substrates was elucidated and broken inversion symmetry in the 3R phase of In₂Se₃ was identified. The presence of in-plane and out-of-plane ferroelectric properties through piezoelectric force microscopy measurements and device-level testing was confirmed.

Metal-Organic Chemical Vapor Deposition of In₂Se₃

To synthesize 2D In₂Se₃ layers, a pulse-modulated metal-organic chemical vapor deposition (MOCVD) technique was employed within a cold-walled, vertical reactor, mirroring the setup utilized for InSe growth (FIG. 1). By adjusting the molecular flow rates of precursors, particularly maintaining a high Se/In ratio (>2), the growth predominantly favored the formation of In₂Se₃ over InSe. This preference is attributed to the accommodation of the excess selenium in the In₂Se₃ crystal structure, which includes an additional Se atomic layer between two In—Se layers. Varying the flow rate of DMSe as a function of growth time narrows the growth window for In₂Se₃, indicating the critical role of the Se/In ratio and pulse duration in influencing phase formation. While constant DMSe flow favors In₂Se₃ formation, a pulsed flow widens the growth window for InSe, promoting nucleation in periodic In-rich environments. Additionally, employing pulsed modulation for the precursor results in higher nucleation density and larger domain sizes across various polymorphs compared to continuous precursor delivery. This suggests that periodic pulses aid in the atomic migration and ripening of the nuclei along the substrate. Due to this rationale, the synthesis of In₂Se₃ relied on pulse-modulation MOCVD as the primary method.

Structural Characterization of In₂Se₃

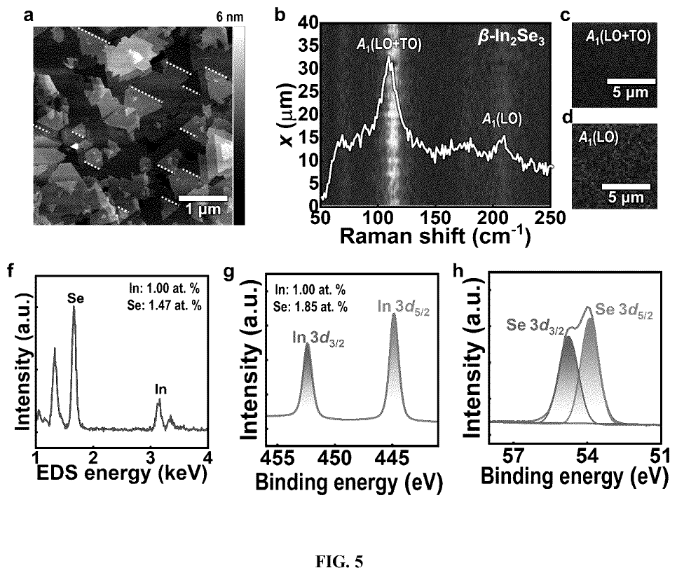

The structural analysis of the In₂Se₃ thin film, with a thickness of approximately 5 nm, has been performed using various characterization techniques. Atomic force microscopy (AFM) reveals a smooth and continuous thin film morphology, as depicted in FIG. 5a. The dashed line in the AFM image suggests the alignment of the 2D domains grown on the film, indicating a well-ordered epitaxial structure. Raman spectroscopy is employed to further characterize the In₂Se₃ film. Raman mapping (FIG. 5b) conducted over 100 positions with a step size of 1 μm provides insights into the homogenous distribution of In₂Se₃ phases across the large area. Additionally, Raman mapping images focused on specific peaks (A₁ (LO+TO) and A₁(LO)) (FIG. 5c and FIG. 5d) confirms the homogeneity of In₂Se₃ vibrational modes across the thin film.

Energy-dispersive X-ray spectroscopy (EDS) analysis (FIG. 5f) indicates stoichiometric In₂Se₃, with an estimated Se/In atomic ratio of ˜1.47, affirming the composition of the thin film. X-ray photoelectron spectroscopy (XPS) further confirms the elemental composition through In 3d and Se 3d scans, providing additional evidence of the film's chemical purity without oxidation (FIG. 5g and FIG. 5h). Note that the higher Se/In ratio (˜1.85) characterized by XPS may be attributed to the absorption of Se atoms onto the top surface of In₂Se₃ due to the growth conducted in a Se-rich atmosphere.

Epitaxial Growth of In₂Se₃

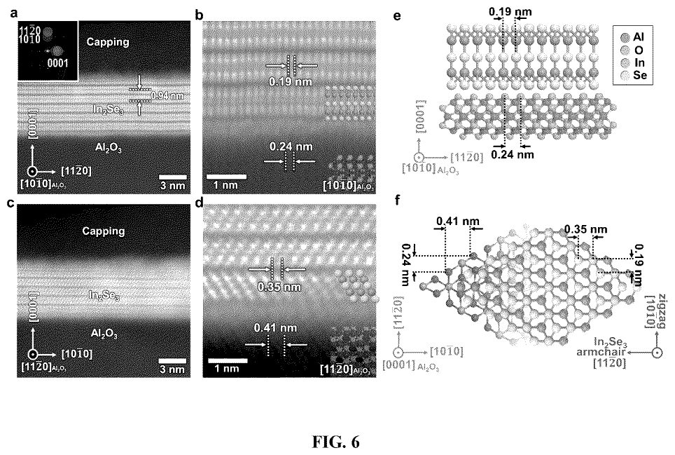

Cross-sectional scanning transmission electron microscopy (STEM) imaging (FIGS. 6a-d) reveals the epitaxial relationship between In₂Se₃ and sapphire (0001). The selected-area electron diffraction (SAED) patterns (inset of FIG. 6a) indicates that the In₂Se₃ grown on sapphire (0001) is single-crystalline, with an epitaxial relation of (0001) In₂Se₃//(0001) Al₂O₃ and [101̅0]_{In2Se3}//[112̅0]_{Al2O3}. In addition, atomic resolution STEM images (FIG. 6b and FIG. 6d) showcase the crystallographic orientations of In₂Se₃ with respect to sapphire, providing insights into the epitaxial alignment. The corresponding cross-section and plan-view schematics (FIG. 6e and FIG. 6f) further summarizes the epitaxial relationship between the In₂Se₃ film and the sapphire (0001) surface, highlighting the alignment and orientation of the crystalline domains.

### Broken Inversion Symmetry and Ferroelectric Properties

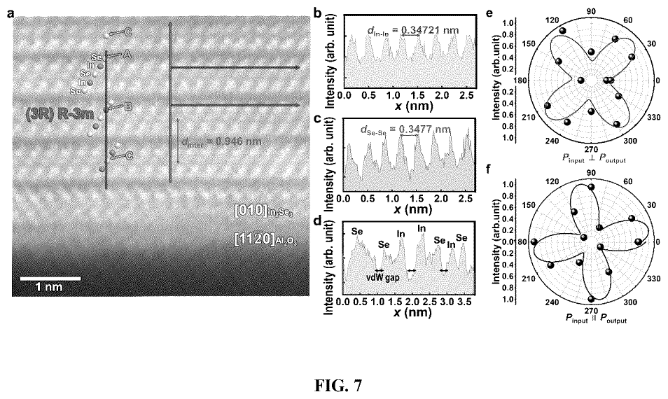

Atomic-resolution STEM imaging (FIG. 7a) reveals the presence of the 3R phase with ABC stacking in the In₂Se₃ crystal, indicating a broken inversion symmetry. Similarly, optical second harmonic generation polar plots (FIG. 7e and FIG. 7f) exhibit the 3m point group symmetry in In₂Se₃, indicative of the broken inversion symmetry in the 3R structure. This asymmetry may trigger out-of-plane ferroelectricity in In₂Se₃, offering potential for novel device applications.

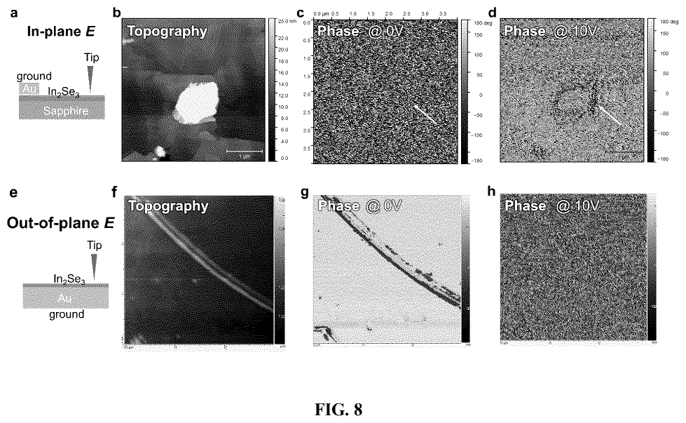

Piezoelectric force microscopy (PFM) characterizations (FIG. 8) further confirmed the presence of in-plane and out-of-plane ferroelectricity in the In₂Se₃ thin film. AFM images depicts the topography of the thin film, while in-plane and out-of-plane PFM phases at different applied voltages provides insights into the ferroelectric properties of the material.

### Ferroelectric Switching Behaviors

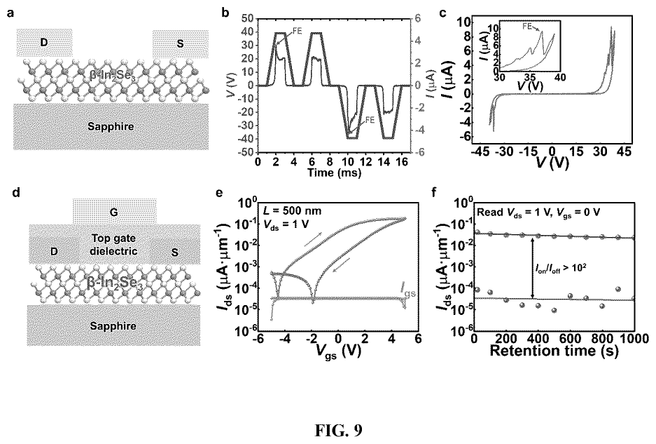

Two-terminal and three-terminal In₂Se₃ devices have been fabricated to investigate ferroelectric switching behaviors (FIG. 9a and FIG. 9b). Positive-up-negative-down (PUND) measurements exhibit pure ferroelectric switching peaks, highlighting the ferroelectric nature of the devices (FIG. 9b). Ferroelectric resistive switching further confirms the presence of ferroelectric currents in the devices (FIG. 9c).

Transfer characteristics of representative In₂Se₃ FeSFETs demonstrates ferroelectric switching at room temperature, with gate currents displayed for comparison (FIG. 9e). On-state current density values corresponding to high-resistance and low-resistance states showed the retention of conductance over time, emphasizing the stability and potential applicability of In₂Se₃ in ferroelectric device technologies (FIG. 9f).

While we have described a number of embodiments of this invention, it is apparent that the basic examples may be altered to provide other embodiments that utilize the compounds and methods of this invention. Therefore, it will be appreciated that the scope of this invention is to be defined by the appended claims rather than by the specific embodiments that have been represented by way of example.

### Example 4-Wafer Scale Epitaxy of 2D-Phase, Rhombohedral-Stacked In₂Ses₃ and its Ferroelectricity

Metal-Organic Chemical Vapor Deposition of In₂Se₃

To synthesize 2D In₂Se₃ layers, a pulse-modulated metal-organic chemical vapor deposition (MOCVD) technique was employed within a cold-walled, vertical reactor, mirroring the setup utilized for InSe growth. By adjusting the molecular flow rates of precursors, particularly maintaining a high Se/In ratio (>2), the growth predominantly favors the formation of In₂Se₃ over InSe. This preference is attributed to the accommodation of the excess selenium in the In₂Se₃ crystal structure, which includes an additional Se atomic layer between two In—Se layers. Varying the flow rate of DMSe as a function of growth time narrows the growth window for In₂Se₃, indicating the critical role of the Se/In ratio and pulse duration in influencing phase formation. While constant DMSe flow favors In₂Se₃ formation, a pulsed flow widens the growth window for InSe, promoting nucleation in periodic In-rich environments. Additionally, employing pulsed modulation for the precursor results in higher nucleation density and larger domain sizes across various polymorphs compared to continuous precursor delivery. This suggests that periodic pulses aid in the atomic migration and ripening of the nuclei along the substrate. Due to this rationale, the synthesis of In₂Se₃ in this investigation predominantly relied on pulse-modulation MOCVD as the primary method.

Structural Characterization of In₂Se₃

The structural analysis of the In₂Se₃ thin film, with a thickness of approximately 5 nm, has been performed using various characterization techniques. Atomic force microscopy (AFM) reveals a smooth and continuous thin film morphology, as depicted in FIG. 5a. The dashed line in the AFM image suggests the alignment of the 2D domains grown on the film, indicating a well-ordered epitaxial structure. Raman spectroscopy is employed to further characterize the In₂Se₃ film. Raman mapping (FIG. 5b) conducted over 100 positions with a step size of 1 μm provides insights into the homogenous distribution of In₂Se₃ phases across the large area. Additionally, Raman mapping images focused on specific peaks (Al (LO+TO) and A₁(LO)) (FIG. 5c, FIG. 5d) confirms the homogeneity of In₂Se₃ vibrational modes across the thin film.

Energy-dispersive X-ray spectroscopy (EDS) analysis (FIG. 5f) indicates stoichiometric In₂Se₃, with an estimated Se/In atomic ratio of ˜1.47, affirming the composition of the thin film. X-ray photoelectron spectroscopy (XPS) further confirms the elemental composition through In 3d and Se 3d scans, providing additional evidence of the film's chemical purity without oxidation (FIG. 5g, FIG. 5h). Note that the higher Se/In ratio (˜1.85) characterized by XPS may be attributed to the absorption of Se atoms onto the top surface of In₂Se₃ due to the growth conducted in a Se-rich atmosphere.

Epitaxial Growth of In₂Se₃

Cross-sectional scanning transmission electron microscopy (STEM) imaging (FIG. 6a, FIG. 6b, FIG. 6c, FIG. 6d) reveals the epitaxial relationship between In₂Se₃ and sapphire (0001). The selected-area electron diffraction (SAED) patterns (inset of FIG. 6a) indicates that the In₂Se₃ grown on sapphire (0001) is single-crystalline, with an epitaxial relation of (0001) In₂Se₃//(0001)_{Al}_{₂}_{O}_{₃}; and [101̅0]_{In2Se3}//[112̅0]_{Al}_{₂}_{O}_{₃}. In addition, atomic resolution STEM images (FIG. 6b, FIG. 6d) showcase the crystallographic orientations of In₂Se₃ with respect to sapphire, providing insights into the epitaxial alignment. The corresponding cross-section and plan-view schematics (FIG. 6e, FIG. 6f) further summarizes the epitaxial relationship between the In₂Se₃ film and the sapphire (0001) surface, highlighting the alignment and orientation of the crystalline domains.

### Broken Inversion Symmetry and Ferroelectric Properties

Atomic-resolution STEM imaging (FIG. 7a) reveals the presence of the 3R phase with ABC stacking in the In₂Se₃ crystal, indicating a broken inversion symmetry. Similarly, optical second harmonic generation polar plots (FIG. 7e, FIG. 7f) exhibit the 3m point group symmetry in In₂Se₃, indicative of the broken inversion symmetry in the 3R structure. This asymmetry may trigger out-of-plane sliding ferroelectricity in In₂Se₃, offering potential for novel device applications.

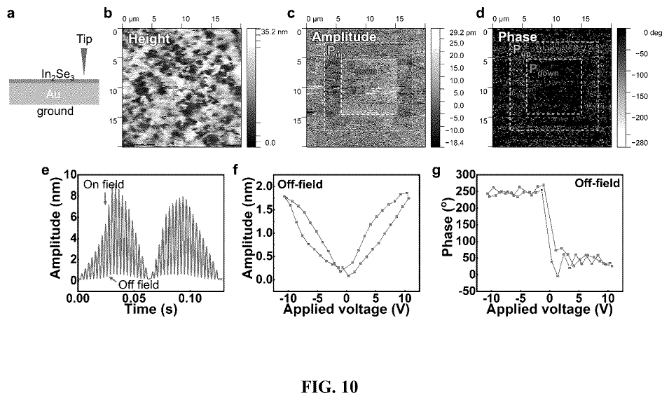

Piezoelectric force microscopy (PFM) characterizations (FIGS. 10a-g) further confirmed the presence of out-of-plane ferroelectricity in the In₂Se₃ thin film. AFM images depict the topography of the thin film, while out-of-plane PFM phases at different applied voltages provides insights into the ferroelectric properties of the material.

### Ferroelectric Field-Effect Transistors

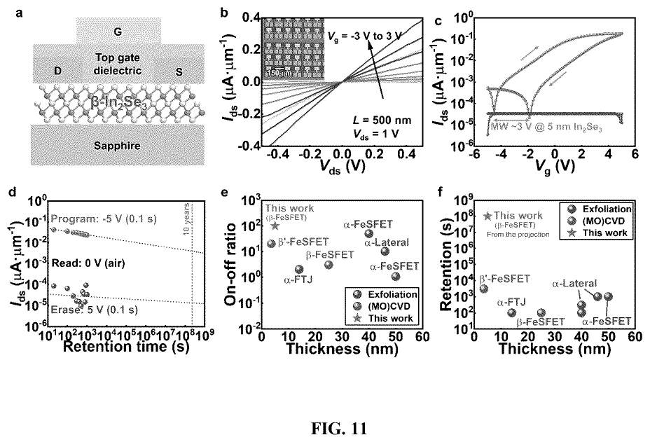

Three-terminal In₂Se₃ ferroelectric semiconductor field-effect transistor (FESFET) have been fabricated to investigate ferroelectric switching behaviors (FIGS. 11a-f). Transfer characteristics of representative In₂Se₃ FeSFETs demonstrates hysteresis of conductance depending on V_{g} at room temperature, attributed to the sliding ferroelectricity. (FIG. 11c). On-state current density values corresponding to high-resistance and low-resistance states showed the retention of conductance over time, emphasizing the stability and potential applicability of In₂Se₃ in ferroelectric device technologies (FIGS. 11d-f). The results are summarized in Table 1 below.

TABLE 1
Comparison of Ferroelectricity in In₂Se₃ Systems.

| Preparation | | | | Thickness | Retention | Retained |
|---|---|---|---|---|---|---|
| methods | Phase | OOP/IP | Device / phase | (nm) | (s) | on-off ratio |
| Exfoliation | α | OOP | FeSFET | 50 | 1000 | 1.0625 |
| | | OOP | MoS₂/In₂Se₃ | 14 | 100 | 2 |
| | | | FTJ | | | |
| | | IP | Lateral two- | 46 | 1000 | 10 |
| | | | terminal device | | | |
| | | OOP | In₂Se₃/Si FJT | 194 | 10000 | 100 |
| | | IP | Lateral two- | 40 | 300 | N/A |
| | | | terminal device | | | |
| | | OOP | FeSFET | 40 | 100 | 50 |
| CVD | β′ | OOP | FeSFET | 3.6 | 3000 | 20 |
| MOCVD | β | OOP | FeSFET | 25 | 100 | 3 |
| MOCVD | β | OOP | FeSFET | 5 | 1000 | 100 |

While we have described a number of embodiments of this invention, it is apparent that our basic examples may be altered to provide other embodiments that utilize the compounds and methods of this invention. Therefore, it will be appreciated that the scope of this invention is to be defined by the appended claims rather than by the specific embodiments that have been represented by way of example.

1. A method of making a phase-pure InSe or In₂Se₃ comprising: depositing on a substrate at least one layer of InSe or In₂Se₃ by metal-organic chemical vapor deposition.

2. The method of claim 1, wherein the at least one layer is epitaxially deposited; or wherein two or more layers are epitaxially deposited; or wherein five or six layers are epitaxially deposited.

3. The method of claim 1, wherein the substrate is a wafer having at least a two inch diameter.

4-6. (canceled)

7. The method of claim 1, wherein the wafer is a wafer selected from a c-plane sapphire wafer, an AlOₓ/Si wafer, and an SiO₂/Si wafer.

8. (canceled)

9. The method of claim 1, further comprising modulating a flow rate of a In starting material and of a Se starting material so as to control a flux ratio of Se/In.

10. The method of claim 9, wherein the flux ratio of Se/In is less than about 2; or the flux ratio of Se/In is from about 0.25 to about 2; or the flux ratio of Se/In is from about 0.5 to about 2; or the flux ratio of Se/In is from about 0.75 to about 2; or the flux ratio of Se/In is from about 1 to about 2; or the flux ratio of Se/In is from about 1.25 to about 2; or the flux ratio of Se/In is from about 1.5 to about 2; or the flux ratio of Se/In is less than about 1.5; or the flux ratio of Se/In is from about 0.25 to about 1.5; or the flux ratio of Se/In is from about 0.5 to about 1.5; or the flux ratio of Se/In is from about 0.75 to about 1.5; or the flux ratio of Se/In is from about 1 to about 1.5; or the flux ratio of Se/In is less than about 1; or the flux ratio of Se/In is from about 0.25 to about 1; or the flux ratio of Se/In is from about 0.5 to about 1; or the flux ratio of Se/In is from about 0.75 to about 1.

11-26. (canceled)

27. The method of claim 9, wherein the flux ratio of Se/In is from about 0.25 to about 0.3; or from about 0.3 to about 0.35; or from about 0.35 to about 0.4; or from about 0.4 to about 0.45; or from about 0.45 to about 0.5; or from about 0.5 to about 0.55; or from about 0.55 to about 0.6; or from about 0.6 to about 0.65; or from about 0.65 to about 0.7; or from about 0.7 to about 0.75; or from about 0.75 to about 0.8; or from about 0.8 to about 0.85; or from about 0.85 to about 0.9; or from about 0.9 to about 0.95; or from about 0.95 to about 1.0; or from about 1.0 to about 1.05; or from about 1.05 to about 1.10; or from about 1.10 to about 1.15; or from about 1.15 to about 1.20; or from about 1.20 to about 1.25; or from about 1.25 to about 1.30; or from about 1.30 to about 1.35; or from about 1.35 to about 1.40; or from about 1.40 to about 1.45; or from about 1.45 to about 1.50; or from about 1.50 to about 1.55; or from about 1.55 to about 1.60; or from about 1.60 to about 1.65; or from about 1.65 to about 1.70; or from about 1.70 to about 1.75; or from about 1.75 to about 1.80; or from about 1.80 to about 1.85; or from about 1.85 to about 1.90; or from about 1.90 to about 1.95; or from about 1.95 to about 2.0.

28. The method of claim 1, wherein the depositing takes place at a temperature of from about 350° C. to about 550° C.; or from about 360° C. to about 500° C.; or from about 400° C. to about 500° C.; or from about 450° C. to about 500° C.; or from about 475° C. to about 500° C.

29-33. (canceled)

34. The method of claim 28, wherein the depositing takes place at a temperature of from about 350° C. to about 360° C.; or from about 360° C. to about 370° C.; or from about 370° C. to about 380° C.; or from about 380° C. to about 390° C.; or from about 390° C. to about 400° C.; or from about 400° C. to about 410° C.; or from about 410° C. to about 420° C.; or from about 420° C. to about 430° C.; or from about 430° C. to about 440° C.; or from about 440° C. to about 450° C.; or from about 450° C. to about 460° C.; or from about 460° C. to about 470° C.; or from about 470° C. to about 480° C.; or from about 480° C. to about 490° C.; or from about 490° C. to about 500° C.; or from about 500° C. to about 510° C.; or from about 510° C. to about 520° C.; or from about 520° C. to about 530° C.; or from about 530° C. to about 540° C.; or from about 540° C. to about 550° C.

35. The method of claim 9, wherein the starting material of In comprises (CH₃)₃ In (TMIn).

36. The method of claim 9, wherein the starting material of Se comprises (CH₃)₂Se (DMSe).

37. The method of claim 9, wherein the flow rate of the starting material of Se is pulsed; or wherein the flow rate of the starting material of Se is from about 1 mmol/min to about 25 mmol/min; or wherein the flow rate of the starting material of Se is from about 5 mmol/min to about 25 mmol/min; or wherein the flow rate of the starting material of Se is from about 10 mmol/min to about 25 mmol/min; or wherein the flow rate of the starting material of Se is from about 15 mmol/min to about 25 mmol/min; or wherein the flow rate of the starting material of Se is from about 20 mmol/min to about 25 mmol/min.

38-42. (canceled)

43. The method of claim 9, wherein the flow rate of the starting material of In is from about 0.1 mmol/min to about 30 mmol/min; or wherein the flow rate of the starting material of In is from about 0.5 mmol/min to about 20 mmol/min; or wherein the flow rate of the starting material of In is from about 0.75 mmol/min to about 10 mmol/min; or wherein the flow rate of the starting material of In is from about 1 mmol/min to about 5 mmol/min.

44-46. (canceled)

47. The method of claim 9, wherein the at least one layer of InSe or In₂Se₃ is grown for about 30 minutes to about 60 minutes; or wherein the at least one layer of InSe or In₂Se₃ is grown for about 35 minutes to about 55 minutes; or wherein the at least one layer of InSe or In₂Se₃ is grown for about 40 minutes to about 50 minutes; or wherein the at least one layer of InSe or In₂Se₃ is grown for about 45 minutes.

48-50. (canceled)

51. A layer of phase-pure InSe or In₂Se₃ made by a method of claim 1.

52. A method of making In₂Se₃, comprising: depositing on a substrate at least one layer of In₂Se₃ by metal-organic chemical vapor deposition on a substrate, the substrate optionally comprising sapphire.

53. The method of claim 52, wherein the vapor deposition comprises pulse modulation of precursor gases.

54. The method of claim 52, wherein the at least one layer of In₂Se₃ is characterized as single-crystalline; or wherein the at least one layer of In₂Se₃ is characterized as having a broken symmetry in a 3R structure.

55. (canceled)

56. The method of claim 1, wherein the at least one layer is a layer of InSe.

57. The method of claim 1, wherein the at least one layer is a layer of In₂Se₃.
